(19) United States
(12) Patent Application Publication
(10) Pub. No.: US 2013/0009846 A1
(43) Pub. Date: Jan. 10, 2013

(54) INSERT FOR RADOMES AND METHODS OF MANUFACTURING INSERT FOR RADOMES

(75) Inventors: Douglas Ward FREITAG, Brookeville, MD (US); Scott MORRISON, Chelmsford, MA (US); Arthur GAVRIN, Litchfield, NH (US); Ken MAHMUD, Sudbury, MA (US)

(73) Assignee: TRITON SYSTEMS, INC., Chelmsford, MA (US)

(21) Appl. No.: 13/534,747

(22) Filed: Jun. 27, 2012

Related U.S. Application Data
(60) Provisional application No. 61/501,627, filed on Jun. 27, 2011.

(51) Int. Cl. H01Q 1/42; G03F 7/20; B29C 35/08; B32B 15/08

(52) U.S. Cl. 343/872; 428/457; 428/172; 428/209; 428/433; 428/344; 430/322; 430/296; 264/400

(57) ABSTRACT

Apparatuses such as inserts for radomes are described herein. The apparatuses and inserts including a metal layer having a frequency selective surface.

### CROSS-REFERENCE TO RELATED APPLICATIONS

This application claims priority to U.S. Provisional Application No. 61/501,627 entitled “Insert for Radomes and Methods of Manufacturing Insert for Radomes” filed Jun. 27, 2011, which is herein incorporated by reference in its entirety.

### BACKGROUND

Radomes, sometimes referred to as radar domes, are typically used to protect a radar antenna and associated electronics while allowing radio waves to pass through. For example, radomes can protect a radar from weather, such as wind, precipitation (e.g., rain, snow, sleet, etc.), and/or wind. Radar systems are also deployed on fast-moving objects (e.g., rockets or missiles) that generate heat due to air resistance. Radomes on such fast-moving objects need to be able to withstand high temperatures and protect the radar systems from damage caused by the high temperatures. For example, the temperature can reach about 900° F. to about 1,000° F. on the outer surfaces of such radomes. Short temperature spikes (e.g., about one to about two seconds) can drive the temperature on the outer surfaces of the radome up to about 1,700° F. Temperatures inside the radome can reach up to about 700° F. Current temperature-resistant radomes are formed out of refractory materials, e.g., glass-ceramics, ceramics, high-temperature polymers, metals, metal alloys and/or include a heat shield (e.g., a removable heat shield). The walls of radomes can have various constructions known to those skilled in the art such as a solid wall, an “A” sandwich, a “B” sandwich, a “C” sandwich, or a multilayer structure.

Radomes can include a frequency-selective surface (“FSS”) that can limit certain frequencies from passing into or out of the radome. A FSS can enhance the efficacy of a radar system. For example, a FSS can reduce interference between antennas operating in nearby frequency ranges (e.g., by filtering out potentially-interfering frequencies). Additionally, a FSS can reduce the occurrence of ghosting. Ghosting can occur due to variations in electrical properties of the radome, such as variations in the dielectric properties and/or thickness of the radome, which can cause a radar system to generate false images that appear to be an actual object or target.

FSSs are currently available on radomes that are exposed to lower temperatures (e.g., less than about 500° F.). Radomes that include a FSS are generally formed out of a composite material where the FSS is incorporated into the composite material. For example, the composite material can include a FSS layer (e.g., a metal pattern) that was formed while the composite material was flat (e.g., planar). Accordingly, known manufacturing techniques such as photolithography can be used to define the FSS. The composite material (including the pre-formed FSS layer) can then be molded into an appropriate shape to form a radome.

Such composite materials are not available for high temperature-resistant radomes that are formed out of refractory materials, e.g., glass-ceramics, ceramics, metals, metal alloys or high temperature polymers. While the interior surface of a high temperature-resistant radome is generally cool enough to support a FSS, it is difficult and expensive to define a FSS on the interior surface because the curvature of the interior surface is complex. The complex curvature makes it difficult to pattern a FSS using known methods (e.g., photolithography). Further, a metal FSS defined on a ceramic radome can become delaminated due to thermal expansion and contraction when the radome is exposed to high temperatures (e.g., about 900° F. to about 1,000° F.). Accordingly, frequency selective surfaces are not currently available for high-temperature resistant radomes.

### SUMMARY

Embodiments of the invention are directed to apparatuses, methods for making the apparatuses, and systems including the apparatuses described herein. In various embodiments the apparatuses may include a temperature-resistant material and a metal layer having a frequency selective surface, wherein the metal layer is disposed on a surface of the temperature-resistant layer. In some embodiments, the metal layer may be a metal such as, for example, tungsten, aluminum, copper, and combinations or alloys thereof. In certain embodiments, the frequency selective surface may include one or more periodic feature, and in particular embodiments, the frequency selective surface may include one or more split ring resonator. In further embodiments, the periodic features of the frequency selective surface may be disposed in a modified grid pattern. In some embodiments, the temperature-resistant material may include a thermoset material or thermoplastic material, and in other embodiments, the thermoset material or thermoplastic material may further include glass fiber, quartz fiber, or combinations thereof. In some embodiments, the apparatus may further include an adhesive layer disposed on the frequency selective surface, and the adhesive layer may be epoxy, cyanate ester, silicone, and combinations thereof. In some embodiments, the apparatus may further include a second a metal layer having a second frequency selective surface, wherein the second metal layer is disposed on a surface of the metal layer. In such embodiments, the frequency selective surface and the second frequency selective surface may limit the transmission of frequencies separate frequency ranges. For example, the frequency selective surface may limit transmission of frequencies in a Ka frequency band and the second frequency selective surface may limit a W frequency band. In particular embodiments, the apparatus may be configured and arranged to be incorporated into a radome.

Further embodiments are directed to various systems including a radome and an insert disposed on the radome, the insert including a temperature-resistant material and a metal layer having a frequency selective surface, wherein the metal layer is disposed on a surface of the temperature-resistant layer. In various embodiments, the insert may be disposed on an interior surface of the radome, an exterior surface of the radome, or combinations thereof. In particular embodiments, the insert, which is similar in structure to the apparatus described above and includes all of the features of the apparatus described above, may further include a second a metal layer having a second frequency selective surface, wherein the second metal layer is disposed on a surface of the metal layer. In such embodiments, the frequency selective surface and the second frequency selective surface may limit the transmission of frequencies separate frequency ranges. For example, the frequency selective surface may limit transmission of frequencies in a Ka frequency band and the second frequency selective surface may limit a W frequency band.

Other embodiments are directed to methods of manufacturing an apparatus (or insert as described in paragraph [0006], the method including, but not being limited to, the steps of molding a first layer into a shape that substantially conforms to a surface of a radome, the first layer comprising a temperature-resistant material, disposing a metal layer on a surface of the first layer, and applying periodic features on an exposed surface of the metal layer. In some embodiments, applying may include the step of disposing a material onto the exposed surface of the metal layer by a means selected from the group consisting of photolithography, three-dimensional photolithography, electron beam lithography, laser-scanning lithography, and combinations thereof, and in some embodiments, applying include the step of disposing a material onto the exposed surface in a pattern selected from the group consisting of a lattice, a split ring resonator, and combinations thereof.

### BRIEF DESCRIPTION OF THE DRAWINGS

The present drawings are provided for the purpose of describing specific embodiments and concepts relating to the present technologies, and are not provided by way of definition or limitation thereof. Accordingly, the present systems and methods can be better illustrated and understood in view of the accompanying drawings, in which:

FIG. 1 is a schematic cross-sectional view of an exemplary radome and insert according to embodiments of the technology.

FIG. 2 is a schematic cross-sectional view of an exemplary insert according to embodiments of the technology.

FIG. 3 is a flow chart depicting an exemplary method of manufacturing an insert according to embodiments of the technology.

### DETAILED DESCRIPTION

Before the present systems, devices and methods are described, it is to be understood that this disclosure is not limited to the particular systems, devices and methods described, as these may vary. It is also to be understood that the terminology used in the description is for the purpose of describing the particular versions or embodiments only, and is not intended to limit the scope.

It must also be noted that as used herein and in the appended claims, the singular forms “a,” “an,” and “the” include plural references unless the context clearly dictates otherwise. Thus, for example, reference to a “pin assembly” is a reference to one or more pin assemblies and equivalents thereof known to those skilled in the art, and so forth. Unless defined otherwise, all technical and scientific terms used herein have the same meanings as commonly understood by one of ordinary skill in the art. Although any methods, materials, and devices similar or equivalent to those described herein can be used in the practice or testing of embodiments, the preferred methods, materials, and devices are now described. All publications mentioned herein are incorporated by reference. All sizes recited herein are by way of example only, and the invention is not limited to structures having the specific sizes or dimensions recited below. Nothing herein is to be construed as an admission that the embodiments described herein are not entitled to antedate such disclosure by virtue of prior invention. As used herein, the term “comprising” means “including, but not limited to.” As used herein, the term “about,” when referring to a value, means plus or minus 10% of the value.

Inserts for a radome, an apparatus including a radome and an insert, and methods of forming same are disclosed herein. The insert includes a first layer, a second layer, and an adhesive layer. The second layer, disposed between the first layer and the adhesive layer, includes a temperature resistant material layer that can be molded or formed into substantially the same shape as a surface (e.g., an interior and/or exterior surface) of a radome. The first layer includes a metal or metal alloy that has a similar coefficient of thermal expansion as the radome material (e.g., material having refractory properties, such as a ceramic, a metal or alloy, and/or a high-temperature polymer). A frequency-selective surface is defined on the first layer. The adhesive layer includes a high-temperature resistant adhesive and is disposed on the second layer. The insert can be adhered to the surface of the radome by pressing the adhesive side of the insert against the surface of the radome. Accordingly, a high-temperature resistant radome that includes a frequency-selective surface can be manufactured according to the apparatus and methods described herein.

Advantages of the insert include the ability to include one or more frequency-selective surfaces on a radome that is exposed to high temperatures (e.g., about 800° F., about 900° F., about 1,000° F., or about 1,100° F., or ranges between any two of these values). For example, a radome on a missile or rocket can be exposed to such high temperatures, which can occur as a result of air resistance during flight. Radomes that are exposed to such high temperatures are typically formed out of materials having refractory properties, such as glass-ceramics (e.g., PYROCERAM®, manufactured by Corning, Inc. of Corning, N.Y.) or silicon nitride (e.g., in-situ reinforced barium aluminosilicate (IRBAS), manufactured by Ceradyne of Costa Mesa, Calif.). A frequency selective surface (“FSS”) can limit the electromagnetic frequencies that can penetrate into or out of the FSS. Advantages of the FSS can include reducing interference of certain electromagnetic frequencies that are close to the operating range of the radar, reducing ghosting, and/or reducing the background noise of certain frequencies. Further, the FSS can allow the design tolerances (e.g., thickness, shape, etc.) of the radome to be increased, thereby reducing the expense of manufacturing the radome and the ghosting effect that can occur.

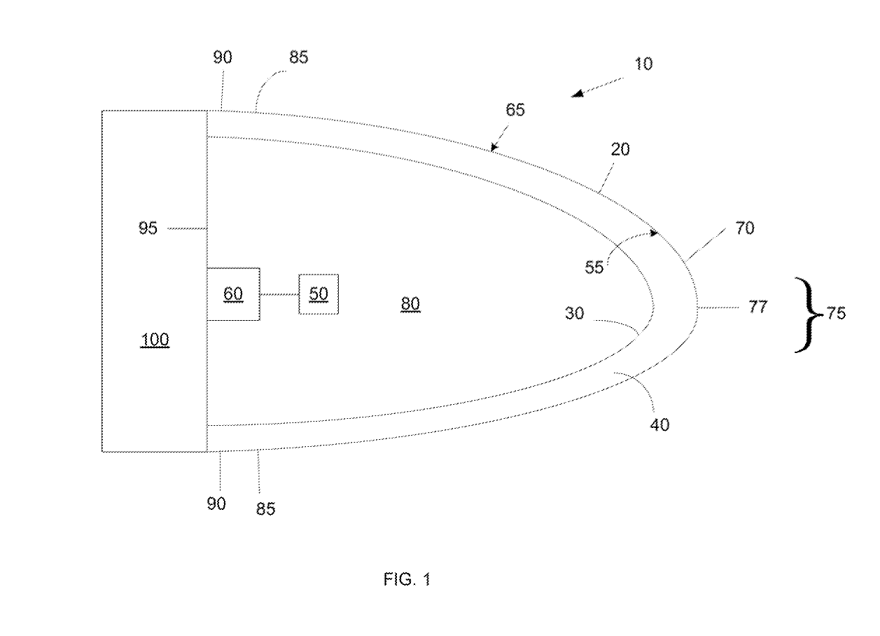

A schematic cross-sectional view of an exemplary radome and insert according to embodiments of the technology is depicted in FIG. 1. The apparatus 10 includes a radome 20, an insert 30, a gap 40, a radar antenna 50, and electronics 60. The radome 20 includes a wall 70 and a hollow center 80. The wall 70 of the radome 20 generally forms a dome or a conical shape depending on the application to reduce aerodynamic drag. Ends 90 of the wall 30 are joined to a base 95 (e.g., a metal ring). This interface can be water-tight to prevent moisture, rain, snow, sleet, hail, etc. from penetrating into the hollow center 80 during storage and operation, which can cause damage to the radar antenna 50 or electronics 60. The base 95 is attached to a bulkhead 100 that can support the base 95, the radar antenna 50 and the electronics 60.

The wall 70 can vary in thickness and can be a solid wall construction. For example, the wall 70 can be thicker at a nose region 75 than at a peripheral region 85. In some embodiments, the wall 70 can have a thickness between about 0.062 inches and about 0.124 inches. The thickness of the wall 70 can be a half wavelength or a multiple of a half wavelength of the operating frequency of the radar system. For example, the wall 70 can be about 0.062 inches (a half wavelength), about 0.124 inches (a full wavelength), 0.186 inches (one and a half wavelengths) or higher, depending on the application, when the operating frequency is about 94 GHz. A thicker wall 70 (i.e., having a thickness that is a higher multiple of a half wavelength of the operating frequency of the radar system) can be employed when enhanced material strength is desired, such as for sustaining increased structural loads, thermal exposure, and/or forces generated by high-speeds (e.g., g-forces, acceleration, etc.). For example, a wall 70 that includes silicon nitride and having a dielectric constant of about 6 to about 7 can have a thickness of at least twice a half wavelength (i.e., a full wavelength) when employed on a radar system that operates in frequencies in the W band (i.e., 75 to 110 GHz). The radome 20 can be constructed with very small thickness tolerances (e.g., less than about 0.01 inches, less than about 0.005 inches, or less than about 0.001 inches) to minimize interference and/or ghosting with electromagnetic radiation (e.g., radio waves) emitted from the radar antenna 50. In some embodiments, the wall 70 is an “A” sandwich, a “B” sandwich, or a “C” sandwich construction. In some embodiments, the nose region 75 of the wall 70 can include a metal or metal alloy tip 77. For example, the metal or metal alloy tip 77 can include a material that is heat-resistant and can withstand exposure to weather (e.g., rain). In some embodiments, the metal or metal alloy includes steel, titanium, or a refractory metal such as tungsten, molybdenum, or tantalum, or a combination of two or more of these materials. In some embodiments, the metal or metal alloy can improve manufacturability and improve reliability of the radome 20. For example, the metal or metal alloy tip 77 on the nose region 75 can enable an operator to secure the nose region 75 of the radome 20 during manufacturing (e.g., while machining the radome 20).

The radome 20 can be constructed out of a material that is transparent or substantially transparent to electromagnetic radiation emitted from or received by the radar antenna 50 and that is high temperature-resistant. Suitable materials can include refractory metals, glass-ceramics or ceramics. For the example, the refractory metal materials can include tungsten, tantalum, or a combination and/or alloys thereof. Ceramics and glass-ceramics can include silicon nitride, silica, alumina, beryllia, cordierite, or PYROCERAM®, manufactured by Corning, Inc. of Corning, N.Y., or combinations thereof. In some embodiments, the radome 20 includes high-temperature polymers such as polytetrafluoroethylene, DUROID®, manufactured by Rogers Corporation of Rogers, Conn., TEFLON®, manufactured by E.I. DuPont de Nemours and Company, Inc. of Wilmington, Del., silicones, silicone copolymers, polyimides, phenolic polymers, or combinations thereof. It will be apparent to one skilled in the art that high-temperature polymers generally are less rigid (e.g., have a lower Young's modulus) than ceramics and refractory metals. Less rigid materials can be less suitable for radomes employed on high-speed devices (e.g., a rocket or missile) because such materials can distort during flight (e.g., due to high g-force maneuvers).

In some embodiments, the radome 20 is formed out of a temperature-resistant material (e.g., a refractory metal, glass-ceramic, and/or a ceramic, as described above) that can withstand temperatures up to about 800° F., about 900° F., about 1,000° F., or about 1,100° F. In some embodiments, the temperature can reach between about 800° F. to about 2000° F., about 1,000° F. to about 1,750° F., about 1,250° F. to about 1,500° F., or ranges between any two of these values. In some embodiments, the temperature can be greater than about 800° F. Higher temperatures can occur at the nose region 75 and the tip 77 of the radome 20. Such temperatures can occur when the radome 20 is disposed on a rocket, missile, or other fast-moving device.

The insert 30 is disposed in the hollow center 80 of the radome 20. The insert 30 substantially conforms to an interior surface 55 of the radome 20. The insert 30 includes a frequency selective surface (“FSS”) that can limit the frequencies of electromagnetic waves that can pass through the insert 30. In some embodiments, the insert 30 conforms to and is disposed on an outer surface 65 of the radome 20 instead of the interior surface 55 of the radome 20. In some embodiments, two or more inserts 30 can be used in combination (e.g., in applications where multi-mode radar antennas are used). For example, two or more inserts 30 can be disposed in the hollow center 80 of the radome 20. For example, a first insert can be disposed on (e.g., adhered to) the interior surface 55 of the radome 20 and a second insert can be disposed on (e.g., adhered to) the first insert. The first insert and the second insert can have FSSs having the same or different properties. For example, the first FSS can limit the transmission of a first frequency range through the first insert and the second FSS can limit the transmission of a second frequency range through the second insert. In a specific embodiment, the first frequency range can include the Ka and W frequency bands (i.e., 26.5 GHz to 110 GHz) and the second frequency range can include only the W band (75 GHz to 110 GHz). Other frequencies or frequency ranges can be limited or selectively-transmitted by the FSS, including the X band (8 GHz to 12 GHz), the Ku band (12 GHz to 18 GHz), the K band (18 GHz to 26.5 GHz), and/or the V band (50 GHz to 65 GHz). Additional inserts 30 can be adhered to one another such that three or more inserts 30 can be adhered to the interior surface 55 of the radome 20. Similarly, two or more inserts 30 can be adhered to the outer surface 65 of the radome 20. Additionally, a combination of the above can occur (e.g., one or more inserts 30 can be adhered to the interior surface 55 and one or more inserts 30 can be adhered to the outer surface 65). In some embodiments, a heat shield can be disposed over the insert 30 when the insert 30 is adhered to the outer surface 65 of the radome 20 or the interior surface 55 of the radome 20.

The thickness tolerance of the radome 20 can be affected by the operating frequency of the radar antenna 50, the electrical and mechanical properties of the radome 20 material(s). When the radome 20 is deployed on a rocket, missile, or other flying device, the flight environment (e.g., g-forces related to high-speed maneuvers, rapid acceleration, altitude, and/or speed of the device) can also affect the thickness tolerance of the radome 20. For example, a radome 20 that includes silicon nitride can have a thickness tolerance of about 0.01 inch to about 0.02 inch when the operating frequency of the radar antenna 50 is in the Kₐ band (i.e., 26.5 GHz to 40 GHz). The thickness tolerance of a radome 20 that includes silicon nitride can be about 0.001 inch to about 0.0001 inch when the operating frequency of the radar antenna 50 is in the W band (i.e., 75 GHz to 110 GHz). The insert 30 can allow the design tolerances (e.g., thickness, shape, etc.) of the radome 20 to be increased, thereby reducing the expense of manufacturing the radome 20. For example, the insert 30 can allow the design tolerance of the radome 20 to be decreased by 10×. Accordingly, a radome 20 that includes silicon nitride and includes a radar antenna 50 that operates in the W band can have a thickness tolerance of about 0.01 inch to about 0.001 inch. This increase in thickness tolerance can enable the manufacture of radomes in high frequency radar systems (e.g., W band and above) because such tight thickness tolerances are expensive to achieve or, in some instances, extremely difficult or impossible to achieve using conventional manufacturing techniques. This increase in thickness tolerance can also relax the need for boresight error correction capabilities built in the electronics resulting from changes in the thickness during flight as the radome heats up and expands. Additionally, the increase in thickness tolerance can reduce the ghosting effect.

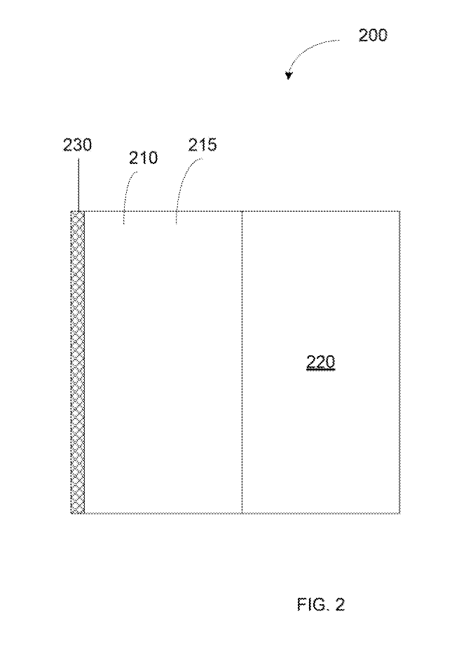

A schematic cross-sectional view of an exemplary insert is depicted in FIG. 2. The insert 200 includes a first layer 210, a second layer 220, and an adhesive layer 230. The first layer 210 is disposed between the second layer 220 and the adhesive layer 230. The first layer 210 includes a metal or metal alloy that has a similar coefficient of thermal expansion as the radome 20. Having a similar coefficient of thermal expansion minimizes stress on the apparatus 10 that can occur due to uneven thermal expansion of the insert 30 or 200 and the radome 20. In some embodiments, the metal can be a high temperature-resistant and non-thermally conducting material. For example, the metal can include tungsten, aluminum, copper, a combination thereof, or an alloy of one or more of these metals. In some embodiments, the first layer 210 can be about 300 nm, about 400 nm, about 500 nm, about 600 nm, or about 700 nm thick, or ranges between any two of these values. The first layer 210 can withstand a temperature up to about 400° F., about 500° F., about 600° F., about 700° F., or ranges between any two of these values.

A FSS 215 is formed from the metal in the first layer 210. The FSS 215 can include a split ring resonator, a modified grid pattern, or other known FSS surfaces. The FSS 215 can be formed by a photolithography process (e.g., a three-dimensional photolithography process). The FSS 215 can limit the electromagnetic frequencies that can pass into or out of the radome 30. For example, the FSS 215 can allow frequencies in the W band of the electromagnetic spectrum (i.e., about 75 to about 110 GHz) to pass through while blocking frequencies outside of the W band. Limiting the electromagnetic frequencies can decrease the amount of radiation that can pass through the radome 20, which can make the radar system more difficult to detect (e.g., by an antimissile tracking system).

The second layer 220 includes a high temperature-resistant material that can be molded (e.g., injection-molded) in a shape that substantially conforms to the interior surface 55 of the wall 30 of the radome 20 (e.g., as depicted in FIG. 1). Suitable materials for the second layer 220 can include a high temperature thermoset (e.g., a polyimide), a high-temperature thermoplastic (e.g., polyether ether ketone (i.e., PEEK)), a copolymer of silicone and the high-temperature thermoset and/or the high-temperature thermoplastic (e.g., epoxy silicone or silicone polyimide), a composite of glass and/or quartz fiber and the high-temperature thermoset and/or the high-temperature thermoplastic, or combinations thereof. The materials selected for the second layer 220 can withstand a temperature up to about 400° F., about 500° F., about 600° F., about 700° F., or ranges between any two of these values. In some embodiments, the second layer 220 includes KAPTON® manufactured by the E.I. DuPont de Nemours and Company, Inc. of Wilmington, Del. The second layer 120 can be about 60 mils, about 70 mils, about 80 mils, about 90 mils, or about 100 mils thick, or ranges between any two of these values.

The adhesive layer 230 is disposed on an opposite side of the FSS 215 as the second layer 220 (i.e., on an exposed surface of the FSS 215). The adhesive layer 230 includes a high temperature-resistant adhesive that can withstand a temperature up to about 400° F., about 500° F., about 600° F., about 700° F., or ranges between any two of these values. Suitable adhesives can include epoxies, cyanate esters, high-temperature silicones, or combinations thereof. The adhesive layer can be about 5 mils, about 10 mils, or about 15 mils thick. In some embodiments, the adhesive layer 130 includes a material that does not absorb electromagnetic radiation (e.g., cyanate esters and/or silicones).

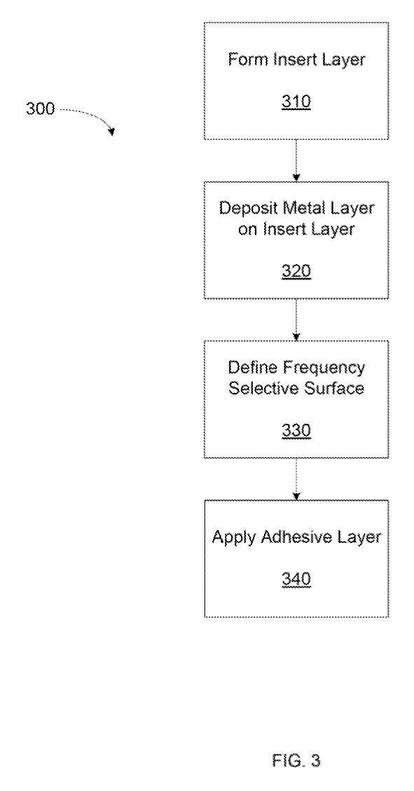

A method of manufacturing an insert is illustrated in a flow chart in FIG. 3. The method 300 includes forming an insert layer (step 310), depositing a metal layer on the insert layer (step 320), defining a frequency selective surface (step 330), and applying an adhesive layer (step 340). In the forming step (step 310), a high temperature-resistant material is molded (e.g., injection-molded, filament wound, and/or autoclaved) into an insert layer having a shape that substantially conforms to a radome (e.g., the interior surface 55 or exterior surface 65 of the radome 20 depicted in FIG. 1). Suitable materials for the insert layer can include a high temperature thermoset (e.g., a polyimide), a high-temperature thermoplastic (e.g., polyether ether ketone (i.e., PEEK)), a copolymer of silicone and the high-temperature thermoset and/or the high-temperature thermoplastic (e.g., epoxy silicone or silicone polyimide), a composite of glass and/or quartz fiber and the high-temperature thermoset and/or the high-temperature thermoplastic, or combinations thereof. The materials selected for the insert layer can withstand a temperature up to about 400° F., about 500° F., about 600° F., about 700° F., or ranges between any two of these values. In some embodiments, the insert layer includes KAPTON® manufactured by the E.I. DuPont de Nemours and Company, Inc. of Wilmington, Del. The insert layer can be about 60 mils, about 70 mils, about 80 mils, about 90 mils, or about 100 mils thick, or ranges between any two of these values. The insert layer can be the same as the second layer 220 in FIG. 2.

In the depositing step (step 320), a metal layer is deposited on the insert layer. Suitable methods include evaporation, physical vapor deposition (e.g., sputtering), printing (e.g., direct write, inkjet, microextrusion, micro-plasma deposition, or similar processes), or other known methods. In some embodiments, the insert layer can be rotated during metal deposition to allow metal deposition across the insert layer surface. The metal can have approximately the same coefficient of thermal expansion as the radome (e.g., the radome 20 in FIG. 1). In some embodiments, the metal can be a high temperature-resistant electrically conducting material. For example, the metal can include tungsten, aluminum, copper, a combination thereof, or an alloy of one or more of these metals. In some embodiments, the metal layer can be about 300, about 400, about 500 nm, about 600 nm, or about 700 nm thick, or ranges between any two of these values. The metal layer can be the same as the first layer 210.

In the defining step (step 330), a FSS is defined from the metal layer. The FSS can include a periodic feature (e.g., a periodic unit cell) defined in the metal layer (e.g., the first layer 210). Suitable methods for defining a FSS can include photolithography, electron beam lithography, three-dimensional photolithography, laser-scanning lithography, or other known methods. For example, the FSS can be patterned with a SF-100™ three-dimensional photolithography system manufactured by Intelligent Micro-Patterning, LLC of St. Petersburg, Fla. Examples of periodic features that can function as an FSS can include spit ring resonators, an array of geometric shapes or features (e.g., gaps), a lattice, or other known structures. The FSS can be the same as the FSS 215 depicted in FIG. 2. After the defining step, the metal layer can be substantially or completely transformed into a FSS (i.e., substantially all or all of the metal deposited in bulk form (step 320) has been removed). A cross section of an exemplary FSS structure is illustrated in FIG. 4.

In the applying step (step 340), an adhesive layer is applied to the FSS layer. The adhesive can be manually applied, spun-on, sprayed on, or applied by other known techniques. As discussed above, the adhesive layer (e.g., the adhesive layer 230) can include a high temperature-resistant adhesive that can withstand a temperature. The adhesive layer can include epoxies, cyanate esters, high-temperature silicones, or combinations thereof. The adhesive layer can be about 5 mils, about 10 mils, or about 15 mils thick. The adhesive (e.g., the adhesive layer 230), the FSS layer (e.g., the FSS 215), and the insert layer (e.g., the second layer 220) together form a frequency-selective insert (e.g., the insert 30) for a radome (e.g., the radome 20).

A method of forming an apparatus includes adhering an insert (e.g., the insert 30) to a surface (e.g., an interior or outside surface) of the radome (e.g., the radome 20). Pressure is then applied on the insert and radome to force the insert to adhere to the surface of the radome. The insert and radome in combination form a radome-insert apparatus (e.g., the apparatus 10) that includes a FSS. Additional inserts can be included in the radome-insert apparatus, as discussed above. For example, a first insert can be adhered to an interior surface of the radome and a second insert can be adhered to the first insert (e.g., an interior surface of the first insert). Additional inserts can be combined in a like manner. Additionally or alternatively, a first insert can be adhered to an outside surface of the radome and a second insert can be adhered to the first insert (e.g., an outside surface of the first insert). Additional inserts can be combined in a like manner. The method can include combinations of the above. For example, a first insert can be adhered to an interior surface of the radome and a second insert can be adhered to an outside surface of the radome. Additional inserts can be adhered to the first and/or second insert as described above.

The present disclosure is not intended to be limited by its preferred embodiments, and other embodiments are also comprehended and within its scope. Numerous other embodiments, modifications and extensions to the present disclosure are intended to be covered by the scope of the present inventions as claimed below. This includes implementation details and features that would be apparent to those skilled in the art in the mechanical, chemical or electronic implementation of the systems and methods described herein.

We claim:

1. An apparatus, comprising:
a temperature-resistant material; and
a metal layer having a frequency selective surface, wherein the metal layer is disposed on a surface of the temperature-resistant layer.

2. The apparatus of claim 1, wherein the metal layer comprises a metal selected from the group consisting of tungsten, aluminum, copper, and combinations or alloys thereof.

3. The apparatus of claim 1, wherein the frequency selective surface comprises one or more periodic feature.

4. The apparatus of claim 1, wherein the frequency selective surface comprises one or more split ring resonator.

5. The apparatus of claim 1, wherein the frequency selective surface comprises periodic features disposed in a modified grid pattern.

6. The apparatus of claim 1, wherein the temperature-resistant material comprises a thermoset material or thermoplastic material.

7. The apparatus of claim 6, wherein the thermoset material or thermoplastic material further comprises glass fiber, quartz fiber, or combinations thereof.

8. The apparatus of claim 1, further comprising an adhesive layer disposed on the frequency selective surface.

9. The apparatus of claim 8, wherein the adhesive layer comprises epoxy, cyanate ester, silicone, and combinations thereof.

10. The apparatus of claim 1, further comprising a second a metal layer having a second frequency selective surface, wherein the second metal layer is disposed on a surface of the metal layer.

11. The apparatus of claim 10, wherein the frequency selective surface and the second frequency selective surface limit the transmission of frequencies separate frequency ranges.

12. The apparatus of claim 10, wherein the frequency selective surface limits transmission of frequencies in a Ka frequency band and the second frequency selective surface limits a W frequency band.

13. The apparatus of claim 1, wherein the apparatus is configured and arranged to be incorporated into a radome.

14. A system comprising:
a radome; and
an insert disposed on the radome, the insert comprising:
a temperature-resistant material; and
a metal layer having a frequency selective surface, wherein the metal layer is disposed on a surface of the temperature-resistant layer.

15. The system of claim 14, wherein the insert is disposed on an interior surface of the radome, an exterior surface of the radome, or combinations thereof.

16. A method of manufacturing an apparatus, the method comprising:
molding a first layer into a shape that substantially conforms to a surface of a radome, the first layer comprising a temperature-resistant material;
disposing a metal layer on a surface of the first layer; and
applying periodic features on an exposed surface of the metal layer.

17. The method of claim 18, wherein applying comprises disposing a material onto the exposed surface of the metal layer by a means selected from the group consisting of photolithography, three-dimensional photolithography, electron beam lithography, laser-scanning lithography, and combinations thereof.

18. The method of claim 18, wherein applying further comprises disposing a material onto the exposed surface in a pattern selected from the group consisting of a lattice, a split ring resonator, and combinations thereof.
